(19) United States
(12) Patent Application Publication
(10) Pub. No.: US 2015/0334841 A1
(43) Pub. Date: Nov. 19, 2015

(54) Printed Circuit Board

(71) Applicant: AT&S AUSTRIA TECHNOLOGIE & SYSTEMTECHNIK AKTIENGESELLSCHAFT, Leoben (AT)

(72) Inventor: Gerhard SCHMID, Trofaiach (AT)

(73) Assignee: AT&S Austria Technologie & Systemtechnik Aktiengesellschaft

(21) Appl. No.: 14/653,228

(22) PCT Filed: Dec. 12, 2013
(86) PCT No.: PCT/AT2013/050249

§ 371 Date: Jun. 17, 2015

(30) Foreign Application Priority Data
Dec. 24, 2012 (CN) 201220717752.6

(51) Int. Cl. H05K 1/18; H05K 1/02; H05K 1/11

(52) U.S. Cl. CPC H05K 1/183; H05K 1/115; H05K 1/181; H05K 1/0298; H05K 2201/09036; H05K 2201/10515

(57) ABSTRACT

A multilayer printed circuit board comprising conductive layers separated by dielectric insulation layers, at least one conductive layer being patterned and parts of conducting layers being interconnected by means of vias traversing insulation layers, and at least one component having terminals electrically connected with conducting layers is countersunk at least partly in a cavity having a floor and side walls, whereby a first component is completely countersunk in the cavity with its terminals connected face-down directly with contacts on the floor of the cavity and at least one further component is stacked above the first component, whereby an edge of the lower surface of the second component projecting over the upper surface area of the at least one further component is provided with terminals being connected directly face-down with contacts of the circuit board arranged on a level higher than the floor of the cavity.

### BACKGROUND OF THE INVENTION

1. Field of the Invention

The present invention relates to a printed circuit board (PCB) and in particular to a multilayer printed circuit board comprising conductive layers separated by dielectric insulation layers, at least one conductive layer being patterned and parts of conducting layers being interconnected by means of vias traversing insulation layers, and at least one component having terminals electrically connected with conducting layers is countersunk at least partly in a cavity having a floor and side walls.

2. Description of the Related Art

Increasing miniaturization and extreme electronic component density as well as the necessity to transfer large amounts of data at high speed, e.g. at rates of 1 to 5 Gbps, can create serious problems with respect to signal integrity in PCBs. Accordingly it is desirable to have short and direct signal lines between components. The demand to produce HDI-PCBs (HDI is a broadly used acronym for “High Density Interconnect”) being physical thinner and having low signal losses created the need for new solutions.

In the field of HDI-structures it is known to dispose single chips in cavities made in layers of a PCB and to stack thereafter these layers together, as disclosed e.g. in U.S. Pat. No. 5,241,456 (Marcinkiewicz et al.).

A circuit board in accordance with the preamble of claim 1 is disclosed in US 200510103522A1. In this case special interconnect packages, housing a component like a semiconductor chip, an IC etc., are used to guide interconnections from the terminals of the component to conducting. The need to embed chips in a supplementary package leads not only to additional costs but also to an increase in overall height (or thickness) of the PCBs.

### SUMMARY

An object of the present invention is to provide a multilayer PCB with components even of different dimensions, without an undue increase of the total height of the PCB.

A further aspect of the present invention is to provide a PCB having short signal lines connecting components with conducting layers of the PCB.

Quite another aspect of the present invention is to provide a HDI-PCB housing several electronic components without using additional packages for the components.

Another object of the invention is the provision of a multilayer PCB with a reduced number of production steps.

Thus the present invention provides a multilayer printed circuit board comprising conductive layers separated by dielectric insulation layers, at least one conductive layer being patterned and parts of conducting layers being interconnected by means of vias traversing insulation layers, and at least one component having terminals electrically connected with conducting layers is countersunk at least partly in a cavity having a floor and side walls. A first component is completely countersunk in the cavity with its terminals connected face-down directly with contacts on the floor of the cavity and at least one further component is stacked above the first component, whereby an edge of the lower surface of at least one further component above projecting over the upper surface area of the at least one component below is provided with terminals being connected directly face-down with contacts of the circuit board arranged on a level higher than the floor of the cavity.

In a preferred embodiment of the invention a second component, stacked above said first component, is connected with contacts of the circuit board which are arranged on the upper surface of the circuit board and which at least partly edge the cavity.

Another recommendable variant of the invention is characterized in that a second component, stacked above said first component, is at least partly countersunk in the cavity, said cavity having an inner step, and the second component is connected with contacts of the circuit board, the contacts being arranged on the upper surface of said step.

It can be advantageous, if the second component is completely countersunk in the cavity.

Another advantageous variant may comprise a third component, stacked above said second component, which is connected with contacts of the circuit board, the contacts being arranged on the upper surface of the circuit board and which at least partly edge the cavity.

In another advantageous embodiment of a printed circuit board the electrical conducting connection between the terminals of a first component and/or the terminals of at least one further component is established using an anisotropic conducting film.

### BRIEF DESCRIPTION OF THE DRAWINGS

FIG. 1 is a schematic cross-sectional view of a PCB according to the invention having six structured layers of conducting material and three electronic components, two of them completely countersunk in a cavity,

FIG. 2 is a simplified view similar to FIG. 1 of a PCB according to the invention having two components stacked over each other and completely countersunk,

FIG. 3 is a simplified view similar to FIG. 1 of a PCB according to the invention having one component countersunk and one component on the surface of the PCB stacked above the countersunk component,

FIG. 4 is a simplified view similar to FIG. 1 of a PCB according to the invention having three components stacked over each other and completely countersunk and one further component on the surface of the PCB stacked above the countersunk components.

### DETAILED DESCRIPTION

Embodiments of a PCB according to the invention will be described below in more detail with reference to the accompanying drawings. For same or similar components same reference numerals are used in order to avoid redundant explanations.

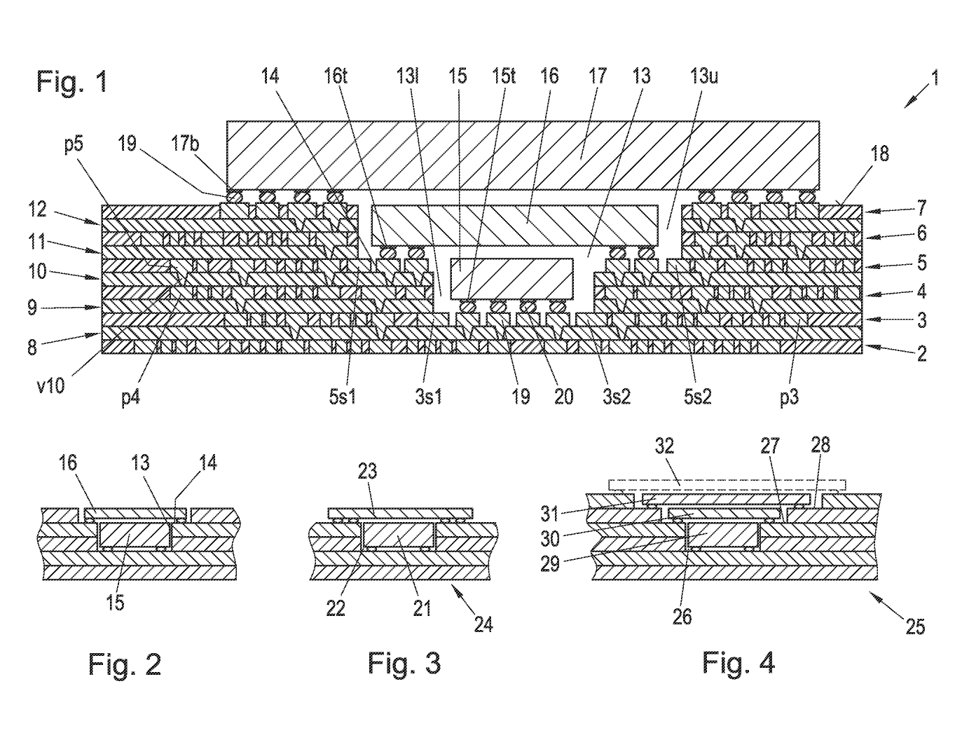

A printed multilayer circuit board 1 with a HDI-structure according to the invention, as shown in FIG. 1, comprises six structured conducting layers of conductive material like copper, the conducting layer designated from bottom to top with reference numerals 2, 3, 4, 5, 6 and 7, the conducting layers being separated by dielectric insulation layers 8, 9, 11 and 12. It can be seen that the conducting layers include a plurality of conducting paths, such as for example p3 in layer 3. Several conducting paths of different layers are connected by conducting vias. As for example conducting paths p4 and p5 are interconnected by a via v10, passing insolating layer 10.

In the circuit board 1 at least one cavity 13 is formed. In this example cavity 13 is open on top and consists of a lower part 131 and an upper part 13u, whereby a circumferential inner step 14 is formed.

A method to form such cavities in a PCB is disclosed e.g. in EP 2119327B1 of the applicant. On the surface area of a structured core, corresponding in shape to the floor of the cavity desired, a release layer is screen-printed, and then a prepreg-layer with a further structured conducting layer is laminated on the upper surface of the PCB and the release layer. Thereafter along the walls of the cavity desired laser cutting is done, whereby a stop-layer of copper stops the laser. In the example of FIG. 1 layers 3s1, 3s2 and 5s1 and 5s2 had been used as stop layers during forming the cavity 13. Other methods to form cavities may be used, e.g. mechanical milling or punching.

Cavity 13 completely houses two electronic components 15 and 16, a first component 15 being countersunk in the lower part 131 of cavity 13 whereas a second component 16 is countersunk in the upper part 13u of cavity 13, stacked on the first component 15. A third component 17 is stacked above said second component 16, thereby extending over said second component 16 and a part of the upper surface 18 of PCB 1.

The first component 15 is countersunk in the lower part 131 of cavity 13 with its terminals 15t connected face-down directly with contacts 19 on the floor of the cavity. Conducting can be effected by using solder bumps 20, as shown in this example, however other methods for establishing an electrical conducting connection between the terminals of a component and a conducting path may be used, for instance using an ACF (anisotropic conducting film) or using a conducting paste.

The second component 16 projects over the upper surface area of the first component 15 and is provided on the edge of its lower surface with terminals 16t, which are connected directly face-down with contacts 19 of the circuit board, arranged on a level higher than the floor of the cavity 13. More exactly the contacts 19 are arranged on the upper surface of step 14. As can be seen from the drawing the upper surface of the second component 16 lies in the same plane approximately as the upper surface 18 of PCB 1.

In the example shown in FIG. 1 the third component 17 is stacked above the second component 16 and in a way similar to the second component the third component is provided on the edge of its lower surface with terminals 17t, which are connected directly face-down with contacts 19 of the circuit board, arranged on a level higher than the step 14 of the cavity 13 and at least partly edging the cavity 13. Here too conducting can be effected by using solder bumps 20 or any other suitable method.

FIG. 2 shows another embodiment of the invention, which corresponds to the example of FIG. 1, however the third component omitted. Accordingly a first and a second component 15, 16 stacked over each other are completely countersunk in a cavity 13 having an inner step 14. Here the printed circuit board is designated with reference numeral 1.

According to FIG. 3 a first component 21 is completely countersunk in a cavity 22 without an inner step with its terminals connected face-down directly with contacts on the floor of the cavity 21 and a further, second component 23 is stacked above the countersunk component 21, in a way like third component 17 is stacked above second component 16 in FIG. 1. Here the printed circuit board is designated with reference numeral 24.

Finally FIG. 4 schematically shows an embodiment of a printed circuit board 25 having a cavity 26 with two steps 27, 28 at different levels, whereby three components stacked over each other are completely countersunk in the cavity 26. A fourth component 32, shown in FIG. 4 with broken lines, may be stacked above or omitted.

In FIGS. 2, 3 and 4 the details shown in FIG. 1 are omitted since it should be clear for an expert that the way to connect components with conducting layers of the PCB will be the same or a similar one as done in FIG. 1. It should further be clear that there is no limitation as to the number of conducting and dielectric layers. The same applies to the number of components stacked one above the other and to the number of inner steps of the cavity. In one PCB combinations of several embodiments are possible, i.e. PCBs having cavities without or with inner steps housing one or several components.

PCBs 1, 24, 25 usually are made by impregnating reinforcing material like glass fibres with resin, e.g. epoxy resin, available under grade designations such as FR-4, FR-5 or others or by using polyimide resin. Prepreg-layers advantageously consist of FR-4, but other dielectric materials, suitable for a lamination process, may be used.

A typical thickness of conductive layers, usually consisting of copper ranges between 1 and 20 μm, a typical thickness of the dielectric layers between 5 and 40 μm.

While the foregoing description is directed to various preferred embodiments of the invention, it should be noted that variations and modifications will be apparent to the skilled person without departing from the scope of the invention, defined by the annexed claims.

1. A multilayer printed circuit board comprising conductive layers separated by dielectric insulation layers, at least one conductive layer being patterned and parts of conducting layers being interconnected by means of vias traversing insulation layers, and at least one component having terminals electrically connected with conducting layers is countersunk at least partly in a cavity having a floor and side walls,
characterized in that
a first component is completely countersunk in the cavity with its terminals connected face-down directly with contacts on the floor of the cavity and at least one further component is stacked above the first component, whereby an edge of the lower surface of the at least one further component above projecting over the upper surface area of the at least one component below is provided with terminals being connected directly face-down with contacts of the circuit board arranged on a level higher than the floor of the cavity.

2. A printed circuit board according to claim 1, characterized in that a second component, stacked above said first component, is connected with contacts of the circuit board which are arranged on the upper surface of the circuit board and which at least partly edge the cavity.

3. A printed circuit board according to claim 1, characterized in that a second component, stacked above said first component, is at least partly countersunk in the cavity, said cavity having an inner step, and the second component is connected with contacts of the circuit board, the contacts being arranged on the upper surface of said step.

4. A printed circuit board according to claim 3, characterized in that the second component is completely countersunk in the cavity.

5. A printed circuit board according to claim 2, characterized in that a third component, stacked above said second component, is connected with contacts of the circuit board, the contacts being arranged on the upper surface of the circuit board and which at least partly edge the cavity.

6. A printed circuit board according to claim 1, characterized in that the electrical conducting connection between the terminals of a first component and/or the terminals of at least one further component is established using an anisotropic conducting film.
